(19) United States
(12) Patent Application Publication
(10) Pub. No.: US 2025/0066935 A1
(43) Pub. Date: Feb. 27, 2025

(54) GAS DIFFUSION LAYER FOR ANION EXCHANGE MEMBRANE ELECTROLYSIS AND MANUFACTURING METHOD THEREFOR

(71) Applicants: HANWHA SOLUTIONS CORPORATION, Seoul (KR); KOREA ADVANCED INSTITUTE OF SCIENCE AND TECHNOLOGY, Yuseong-gu, Daejeon (KR)

(72) Inventors: Myung Seok OH, Daejeon (KR); Joung Hoon PARK, Daejeon (KR); Do Heung KIM, Daejeon (KR); Eui-Duk KIM, Daejeon (KR); Sarang PARK, Daejeon (KR); Hyojin JEON, Daejeon (KR); Sung Gap IM, Daejeon (KR); Jin RYU, Daejeon (KR)

(73) Assignees: HANWHA SOLUTIONS CORPORATION, Seoul (KR); KOREA ADVANCED INSTITUTE OF SCIENCE AND TECHNOLOGY, Yuseong-gu, Daejeon (KR)

(21) Appl. No.: 18/714,460

(22) PCT Filed: Nov. 30, 2022
(86) PCT No.: PCT/KR2022/019144

§ 371 Date: May 29, 2024

(30) Foreign Application Priority Data
Nov. 30, 2021 (KR) 10-2021-0169323

(51) Int. Cl. C25B 11/069; C25B 9/23; C25B 11/032; C25B 11/056

(52) U.S. Cl. CPC C25B 11/069; C25B 9/23; C25B 11/032; C25B 11/056

(57) ABSTRACT

The present invention relates to a gas diffusion layer for anion exchange membrane electrolysis which is hydrophilic and has alkali resistance, and further maintains high porosity and low electrical resistance, and a manufacturing method therefor.

### TECHNICAL FIELD

### Cross-Reference to Related Application(s)

This application claims the benefit of Korean Patent Application No. 10-2021-0169323 filed on Nov. 30, 2021 in the Korean Intellectual Property Office, the disclosure of which is incorporated herein by reference in its entirety.

The present invention relates to a gas diffusion layer for anion exchange membrane electrolysis and a manufacturing method therefor.

### BACKGROUND

The gas diffusion layer (GDL) serves as a passage that transmits reactants from a fuel cell (FC) and electrolysis (EC) to an electrode and simultaneously discharges products, and also is a key component that plays roles such as heat dissipation and electrode support.

Most of commercial GDLs are for polymer electrolyte membrane fuel cells (PEMFC) and have a structure in which a microporous layer (MPL) containing a hydrophobic polymer is coated onto a porous carbon paper. At this time, in the case of a fuel cell, a phenomenon (water flooding) may occur where water generated at the cathode blocks the pores of the gas diffusion layer, and thus the gas diffusion layer is required to have hydrophobicity. Therefore, the gas diffusion layer of the fuel cell uses PTFE and a binder as a polymer to impart hydrophobicity.

However, in the case of anion exchange membrane electrolysis, smooth movement of the electrolyte is required, and therefore, unlike a fuel cell, a hydrophobic gas diffusion layer is not suitable. In other words, it is necessary to improve wettability with electrolyte in terms of mass transfer. For this purpose, it is advantageous according as the hydrophilicity of the gas diffusion layer increases. In addition, since a highly concentrated KOH aqueous solution is used as the electrolyte, it is preferable that the gas diffusion layer has high alkali resistance.

Therefore, there is a need to develop a gas diffusion layer that is hydrophilic and has high alkali resistance that can be used in anion exchange membrane electrolysis.

### DETAILED DESCRIPTION OF THE INVENTION

### Technical Problem

It is an object of the present invention to provide a gas diffusion layer for anion exchange membrane electrolysis and a manufacturing method therefor.

Specifically, it is an object of the present invention to provide a gas diffusion layer for anion exchange membrane electrolysis which is hydrophilic and has alkali resistance, and further maintains high porosity and low electrical resistance, and a manufacturing method therefor.

### Technical Solution

According to one embodiment of the present invention, there is provided a gas diffusion layer for anion exchange membrane electrolysis comprising: a porous support; and a polymer thin film deposited on the whole or a part of the surface of the porous support, wherein the polymer thin film includes at least one functional group selected from the group consisting of amine, hydroxyl, ester, acid anhydride, carboxyl, epoxy, and pyridine.

According to another embodiment of the present invention, there is provided a method for manufacturing a gas diffusion layer for anion exchange membrane electrolysis, the method comprising: preparing a porous support (step 1); and forming a polymer thin film deposited on the whole or a part of the surface of the porous support using an initiated chemical vapor deposition (iCVD) (step 2).

### Advantageous Effects

In accordance with the present invention, a gas diffusion layer for anion exchange membrane electrolysis which is hydrophilic and has alkali resistance can be provided.

Also, in accordance with the present invention, a gas diffusion layer for anion exchange membrane electrolysis which maintains high porosity and low electrical resistance can be provided.

In addition, in accordance with the present invention, a method for manufacturing a gas diffusion layer for anion exchange membrane electrolysis using an initiated chemical vapor deposition can be provided.

Further, in accordance with the present invention, since the gas diffusion layer is manufactured using an initiated chemical vapor deposition, the whole of the porous support can be effectively surface modified at a very thin thickness.

### BRIEF DESCRIPTION OF THE DRAWINGS

FIG. 1 is a schematic diagram of a gas diffusion layer for anion exchange membrane electrolysis according to an embodiment of the present invention.

FIG. 2 is a schematic diagram of a gas diffusion layer for anion exchange membrane electrolysis according to another embodiment of the present invention.

FIG. 3 shows surface observation images of a porous support before and after deposition of a thin polymer film according to an embodiment of the present invention through a scanning electron microscope (SEM).

FIG. 4 shows an observation image through a contact angle analyzer (DSA, KRUSS) to measure the contact angle of the carbon paper of a comparative example of the present invention.

FIG. 5 shows an observation image through a contact angle analyzer (DSA, KRUSS) to measure the contact angle of a gas diffusion layer in which a microporous layer was formed on one surface of carbon paper in a comparative example of the present invention.

FIG. 6 shows an observation image through a contact angle analyzer (DSA, KRUSS) to measure the contact angle of the gas diffusion layer on which a polymer thin film is formed on one surface of carbon paper in an embodiment of the present invention.

FIG. 7 shows an observation image through a contact angle analyzer (DSA, KRUSS) to measure the contact angle of a gas diffusion layer on which a microporous layer is formed on one surface of the carbon paper of an embodiment of the present invention and a polymer thin film is formed thereon.

FIG. 8 is a graph showing FT-IR measurement results before and after an alkali resistance test of a gas diffusion layer in which a polymer thin film is formed on one surface of carbon paper in an embodiment of the present invention.

FIG. 9 shows the results of measuring the average electrical resistance value compared to the compression rate in an experimental example of the present invention.

FIG. 10 shows the results of measuring the average electrical resistance value compared to the compression ratio in an experimental example of the present invention.

FIG. 11 shows the results of measuring the average electrical resistance value compared to the compression ratio in an experimental example of the present invention.

FIG. 12 shows the results of measuring the average electrical resistance value compared to the compression ratio in an experimental example of the present invention.

FIG. 13 shows the results of measuring the gas permeability in an experimental example of the present invention.

### DETAILED DESCRIPTION OF THE EMBODIMENTS

The terms “first”, “second”, etc. may be used herein to describe various elements, and these terms are used to distinguish one element from another.

Also, the terminology used herein is for the purpose of describing particular example embodiments only and is not intended to be limiting of the invention. As used herein, the singular forms “a,” “an” and “the” are intended to include the plural forms as well, unless the context clearly indicates otherwise. It will be further understood that the terms “include,” “comprise,” or “have” when used herein, specify the presence of stated features, numbers, steps, elements, or combinations thereof, but do not preclude the presence or addition of one or more other features, numbers, steps, elements, or combinations thereof.

Also, it means that, when each layer or element is referred to as being formed “on” or “top” of the respective layers or elements, each layer or element is formed on the top of the respective layers or elements, or the other layer or element may be additionally formed between the respective layers, or on the object or the substrate.

While the present invention is susceptible to various modifications and alternative forms, specific embodiments will be illustrated and described in detail as follows. It should be understood, however, that the description is not intended to limit the present invention to the particular forms disclosed herein, but the intention is to cover all modifications, equivalents, and replacements falling within the spirit and scope of the invention.

In the anion exchange membrane electrolysis, as the hydrophilicity of the gas diffusion layer increases, the wettability and permeability of the electrolytic solution increase, and thus the efficiency of the cell can increase. Therefore, the existing gas diffusion layer for fuel cells having a hydrophobic microporous layer reduces the wettability of the electrolyte solution, and at the same time, the thickness of the microporous layer, which reaches several tens of micrometers (μm), can also be a cause of decreasing the porosity of the porous support of the gas diffusion layer.

Therefore, the hydrophilic surface modification of the porous supports through thin nanometer-scale polymer thin films is required. In addition, during the water electrolysis process, especially in the case of anion exchange membrane water electrolysis, a highly concentrated KOH aqueous solution is used as the electrolytic solution, and thus the polymer thin film needs to have high alkali resistance in addition to hydrophilicity.

Below, the gas diffusion layer for anion exchange membrane electrolysis of the present invention will be discussed in more detail.

The present invention seeks to provide a gas diffusion layer for anion exchange membrane electrolysis which is hydrophilic and has high alkali resistance, and further maintains high porosity and low electrical resistance.

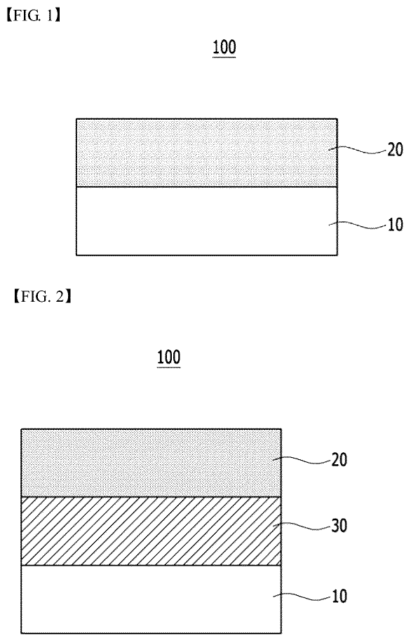

FIG. 1 is a schematic diagram of a gas diffusion layer for anion exchange membrane electrolysis according to an embodiment of the present invention.

The present invention seeks to provide a gas diffusion layer 100 for anion exchange membrane electrolysis comprising: a porous support 10, and a polymer thin film 20 deposited on the whole or a part of the surface of the porous support, wherein the polymer thin film includes at least one functional group selected from the group consisting of amine, hydroxyl, ester, acid anhydride, carboxyl, epoxy, and pyridine.

The functional group contained in the polymer thin film 20 can impart hydrophilic properties to the polymer thin film and also impart high alkali resistance.

Moreover, the polymer thin film 20 may have a thickness of 10 to 200 nm. Specifically, the polymer thin film may have a thickness of 10 nm or more, 25 nm or more, 50 nm or more, 75 nm or more, or 100 nm or more, and 200 nm or less, 175 nm or less, 150 nm or less, or 125 nm or less.

Further, the polymer thin film 20 may include repeating units derived from one or more monomers selected from the group consisting of vinylpyridine, hydroxyalkyl (meth) acrylate, dimethylaminoalkyl (meth) acrylate, dimethylaminoalkyl styrene, ethylene glycol (meth) acrylate, ethylene glycol di(meth) acrylate, styrene-co-maleic anhydride and (meth) acrylic acid. Specifically, the polymer thin film may include the following repeating units.

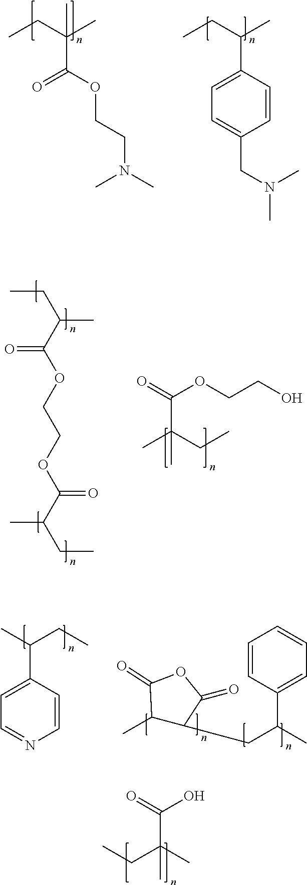

Among these, 2-vinylpyridine or 4-vinylpyridine can be preferably used as a monomer. The pyridine-based monomer has a high pKa, and thus can exhibit excellent alkali resistance.

By containing the repeating unit, the polymer thin film 20 has one or more functional groups selected from the group consisting of amine, hydroxyl, ester, acid anhydride, carboxyl, epoxy, and pyridine, and thus exhibits hydrophilicity.

The gas diffusion layer 100 for anion exchange membrane electrolysis may have a water contact angle of 50° or less. Since the gas diffusion layer of the present invention exhibits hydrophilicity, it is preferable that the lower limit of the water contact angle is not limited. Specifically, the water contact angle may be 40° or less, 30° or less, 20° or less, 10° or less, or 0°.

The water contact angle can be obtained by dropping a drop (10 μl) of distilled water on the surface of the gas diffusion layer before and after modification, photographing the droplet with a contact angle analyzer (DSA, KRUSS), and measuring the contact angle. The contact angle measurement method was in accordance with Korean Patent No. 1644025.

Further, the gas diffusion layer 100 for anion exchange membrane electrolysis may have a gas permeability of 1×10₋₁₂ m² or more. The gas diffusion layer 100 for anion exchange membrane electrolysis of the present invention is a better product as the gas permeability is higher. Therefore, it is preferable that the upper limit thereof is not limited. Specifically, the gas permeability may be 1×10 m² or more, 5×10₋₁₂ m² or more, 10×10₋₁₂ m² or more, 30×10₋₁₂ m² or more, 40×10₋₁₂ m² or more, 50×10₋₁₂ m² or more, or 60×10⁻¹² m² or more, and 80×10₋₁₂ m² or less, 70×10⁻¹² m² or less, or 65×10₋₁₂ m² or less.

The gas permeability of the present invention was measured using a device for evaluating GDL basic physical properties (CPRT 10, Korea Institute of Energy Technology's own standard). By randomly contacting the GDL surface with an area of 0.332 cm² and performing measurements three times in total, the gas permeability can be determined using the following paper and Equation 1.

The gas permeability was determined using the Trough plane permeability method described in the paper “In-plane and through-plane gas permeability of carbon ber electrode backing layers (Jeff T. Gostick, et al., Sep. 1, 2006),” and the gas permeability (K, unit m²) can be calculated according to the following [Equation 1].

$$K = \frac{μ}{A / t} \frac{m}{{P}_{1} - {P}_{2}} ( \frac{RT}{{MP}_{agg}} ) \qquad [ Equation 1 ]$$

in Equation 1,
K is the gas permeability (m²),
μ is the dynamic viscosity of the gas used,
A is the area of the cross section through which gas permeated,
t is the thickness of the gas diffusion layer through which the gas penetrated,
m is the flow rate (mass) of gas flowing through a unit area,
P₁ is the pressure before gas permeation,
P₂ is the pressure after gas permeation,
R is the gas constant,
T is the temperature,
M is the weight of the gas used, and
P_{avg} means the average value of P₁ and P₂.

Further, the gas diffusion layer 100 for anion exchange membrane electrolysis may have may have alkali resistance in a 1M KOH aqueous solution. Specifically, the gas diffusion layer 100 for anion exchange membrane electrolysis of the present invention does not lose its hydrophilicity even when stored in 1M KOH for 3 days, and decomposition or peeling of the thin film does not appear.

The porous support 10 contained in the gas diffusion layer 100 for anion exchange membrane electrolysis of the present invention is not limited as long as it is a porous material, but may be, for example, porous carbon in the form of cloth, felt, or paper, nickel or titanium in the form of mesh, or the like. Specifically, it may be porous carbon paper. In addition, the porous support may have a thickness of 100 to 500 μm.

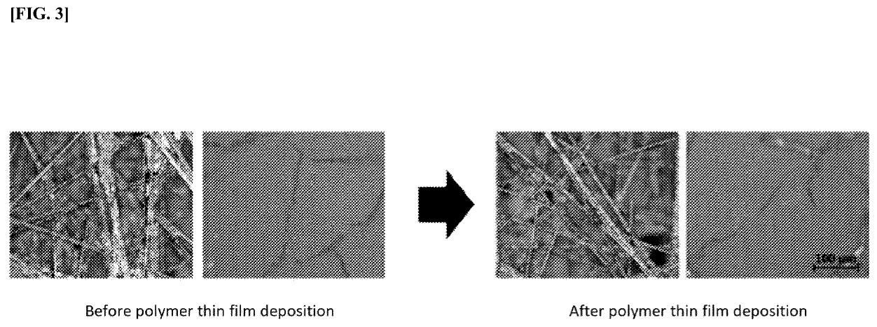

FIG. 2 is a schematic diagram of a gas diffusion layer for anion exchange membrane electrolysis according to another embodiment of the present invention.

Referring to FIG. 2, the gas diffusion layer 100 for anion exchange membrane electrolysis may further comprise a microporous layer 30 containing polytetrafluoroethylene (PTFE) between the porous support 10 and the polymer thin film 20. The microporous layer 30 containing polytetrafluoroethylene (PTFE) may have a thickness of 50 to 200 μm.

In addition, according to the present invention, there can be provided a method for manufacturing the gas diffusion layer for anion exchange membrane electrolysis.

The method for manufacturing the gas diffusion layer for anion exchange membrane electrolysis of the present invention may comprise preparing a porous support (step 1); and forming a polymer thin film deposited on the whole or a part of the surface of the porous support using an initiated chemical vapor deposition (step 2).

The porous support in (step 1) is not limited as long as it is a porous material, but may be, for example, at least one selected from the group consisting of a porous carbon cloth, a porous carbon felt, a porous carbon paper, a nickel mesh, and a titanium mesh. Specifically, the porous support may be a porous carbon paper.

The initiated chemical vapor deposition (iCVD) used in the (step 2) is a process in which nanoscale polymeric thin films are deposited in the vapor phase on various types of substrates. This method allows a thin film to be deposited uniformly and has the characteristic that the surface of the substrate, namely, the gas diffusion layer, can be modified without affecting its porosity and electrical resistance. In particular, according to the present invention, a hydrophilic polymer thin film having high alkali resistance can be deposited on a porous support through an initiated chemical vapor deposition, thereby providing a method for manufacturing a gas diffusion layer for anion exchange membrane electrolysis through surface modification of a porous support, regardless of the presence or absence of a microporous layer.

Specifically, iCVD is a technique that causes polymerization of monomers by decomposing a gaseous initiator into radicals. Peroxides such as tert-butyl peroxide are mainly used as initiators, wherein such materials are volatile materials having a boiling point of about 110° C., which undergoes thermal decomposition at about 150° C. In addition to the initiator such as peroxide, which is decomposed by heat to form radicals, benzophenone, etc. which is decomposed by UV and light to form radicals, can also be used.

The iCVD process deposits a thin film using an energy supply such as a heated filament heat source or UV light. In particular, the iCVD process is performed at a low filament temperature between 180° C. and 350° C., and the temperature of the substrate surface on which the polymer thin film is deposited can be maintained as low as 10 to 50° C. This has the advantage that since the substrate surface temperature can be maintained low, the porous support prepared in the (step 1) is subjected to a high-temperature process to thereby prevent occurrent of defects such as thermal shrinkage. In addition, since the process is performed in a vacuum state where the pressure in the chamber is between 0.01 and 1 Torr, high vacuum equipment is not required, and the monomer and initiator flow rates can be controlled using an injection valve.

In the (step 2), at least one functional group selected from the group consisting of amine, hydroxyl, ester, acid anhydride, carboxyl, epoxy, and pyridine can be used as a monomer for the polymer thin film.

Specifically, the monomer may include a pyridine-based vinyl or acrylate monomer, a hydroxyalkyl-based acrylate monomer, and a tertiary amine-based monomer.

For example, the polymer thin film may include repeating units derived from one or more monomers selected from the group consisting of vinylpyridine, hydroxyalkyl (meth) acrylate, dimethylaminoalkyl (meth) acrylate, dimethylaminoalkyl styrene, ethylene glycol (meth) acrylate, ethylene glycol di(meth) acrylate, styrene-co-maleic anhydride and (meth) acrylic acid.

Further, the (step 2) may be a step of using tert-butyl peroxide, tert-butyl peroxybenzoate, and the like as an initiator for the initiated chemical vapor deposition.

The (step 2) may be performed under a pressure in the reactor chamber of 0.01 Torr to 1 Torr. Specifically, the pressure in the reactor chamber may be 0.01 Torr or more, 0.1 Torr or more, 0.2 Torr or more, or 0.3 Torr or more, and 1 Torr or less, 0.8 Torr or less, 0.6 Torr or less, or 0.4 Torr or less. If the pressure in the reactor chamber is too low or too high, there may be a problem that the polymer thin film is not deposited on the porous support or the deposition rate is slowed.

The (step 2) may be performed at a substrate temperature in the reactor of 10 to 50° C. Specifically, it may be performed at a substrate temperature in the reactor of 10° C. or more, 20° C. or more, or 30° C. or more, and 50° C. or less, or 40° C. or less. If the temperature of the substrate is less than 10° C., there may be a problem that the deposition uniformity of the polymer thin film decreases, and if the temperature of the substrate exceeds 50° C., there may be a problem that the deposition rate become slow.

In the (step 2), the monomer flow rate in the reactor may be 1 sccm to 10 sccm. Specifically, the monomer flow rate is 1 sccm or more, or 2 sccm or more, and 10 sccm or less, 5 sccm or less, or 4 sccm or less.

Further, in the (step 2), the initiator flow rate in the reactor may be 1 sccm to 5 sccm. Specifically, the initiator flow rate may be 1 sccm or more, and 5 sccm or less, 3 sccm or less, or 2 sccm or less.

If the monomer flow rate or the initiator flow rate is too low or high, the deposition thickness may become too thin or too thick even if the deposition time is sufficient.

The polymer thin film deposition of the (step 2) can be performed on one side or both sides of the porous support. When performed on both sides, the iCVD process can be performed repeatedly according to the above-mentioned conditions.

The polymer thin film deposited by the above manufacturing method in a form that covers the whole or at least a part of the surface of the porous support is not formed as a sheet-shaped thin film on a porous support, but is deposited in a form that maintains the pore structure of the porous support. Thereby, the porous characteristics of the porous support can be maintained.

Hereinafter, preferable examples are presented for better understanding the present invention. However, the following examples are only for illustrating the present invention, and the present invention is not limited to or by them.

### EXAMPLE

Porous carbon paper (available from JNTG product name: JNT20) was prepared as a porous support. Then, 4-vinyl pyridine (4-VP) (Aldrich, purity 95%) was placed as a monomer for the polymer thin film into a storage container of a custom-built iCVD reactor (Daeki Hi-Tech, iCVD system), and heated to 45° C. Then, tert-butyl peroxide (Aldrich, purity 98%) as the initiator was placed in an initiator container and maintained at room temperature. At this time, the initiator tert-butyl peroxide was flowed at a flow rate of 1.172 sccm, and the monomer 4-vinyl pyridine (4-VP) was flowed at a flow rate of 3.515 sccm. Porous carbon paper as the porous support was loaded into the reactor, and the temperature of the substrate inside the reactor was maintained at 30° C. In the state where the filament temperature was set to 140° C. and the pressure was set to 0.3 Torr, the initiated chemical vapor deposition was performed on only one side of the porous support for 30 minutes, thereby obtaining a gas diffusion layer in which a 50 nm thick polymer thin film was formed on one surface of the porous carbon paper.

### Example 2

Porous carbon paper (available from JNTG product name: JNT20-A6H) in which a microporous layer containing PTFE was formed on one surface was prepared. JNT20-A6H has a thickness of 250±20 μm, can be operated under high humidity conditions, has an electrical resistance of 10 mOhm·cm² or less, and a density of 100±10 g/m².

Subsequently, a polymer thin film was formed on the microporous layer containing PTFE using the same method and flow rate as in Example 1 to obtain a gas diffusion layer.

### Example 3

A multilayered GDL (available from JNTG, product name: JNT20-A3) in which a microporous layer containing PTFE was coated onto a porous carbon paper was prepared. JNT20-A3 has a thickness of 250±20 μm, can be operated under high humidity conditions, has an electrical resistance of 15 mOhm·cm² or less, and a density of 95±10 g/m².

Subsequently, a polymer thin film was formed on the microporous layer containing PTFE using the same method and flow rate as in Example 1 to obtain a gas diffusion layer.

### Example 4

A multilayered GDL (available from JNTG product name: JNT20-A6L) in which a microporous layer containing PTFE was coated onto a porous carbon paper was prepared. JNT20-A6L has a thickness of 250±20 μm, can be operated under low humidity conditions, has an electrical resistance of 10 mOhm·cm² or less, and a density of 95±10 g/m².

Subsequently, a polymer thin film was formed on the microporous layer containing PTFE using the same method and flow rate as in Example 1 to obtain a gas diffusion layer.

### Comparative Example 1

A clean porous carbon paper on which no microporous layer or thin polymer film was formed was prepared in Comparative Example 1.

### Comparative Example 2

A porous carbon paper (available from JNTG, product name: JNT20-A6H) on which a microporous layer containing PTFE was formed on one surface was prepared in Comparative Example 2.

### Comparative Example 3

A porous carbon paper (available from JNTG product name: JNT20-A3) on which a microporous layer containing PTFE was formed on one surface was prepared in Comparative Example 3.

### Comparative Example 4

A porous carbon paper (available from JNTG, product name: JNT20-A6L & A6H) on which a microporous layer containing PTFE was formed on one surface was prepared in Comparative Example 4.

### Experimental Example 1—Surface Observation of Porous Support Before and After Polymer Thin Film Deposition

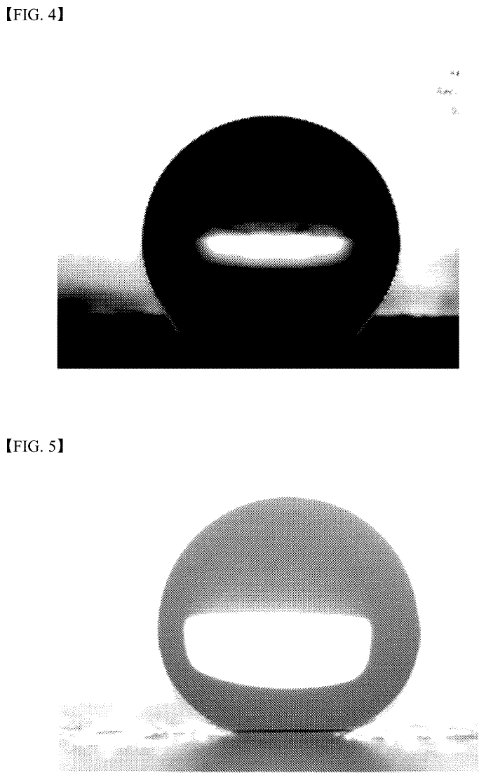

The surfaces of Example 1 and Comparative Example 1 were observed using SEM, and the results were shown in FIG. 3.

It could be confirmed that no changes were observed in the surface of Comparative Example 1 and the surface of Example 1, particularly, no changes were seen in porosity.

### Experimental Example 2—Measurement of Contact Angle

The contact angles of the gas diffusion layers of Example 1, Example 2, Comparative Example 1, and Comparative Example 2 were measured. The contact angle was measured by dropping a drop (10 μl) of distilled water on the surface of the gas diffusion layer before and after modification using a contact angle analyzer (DSA, KRUSS).

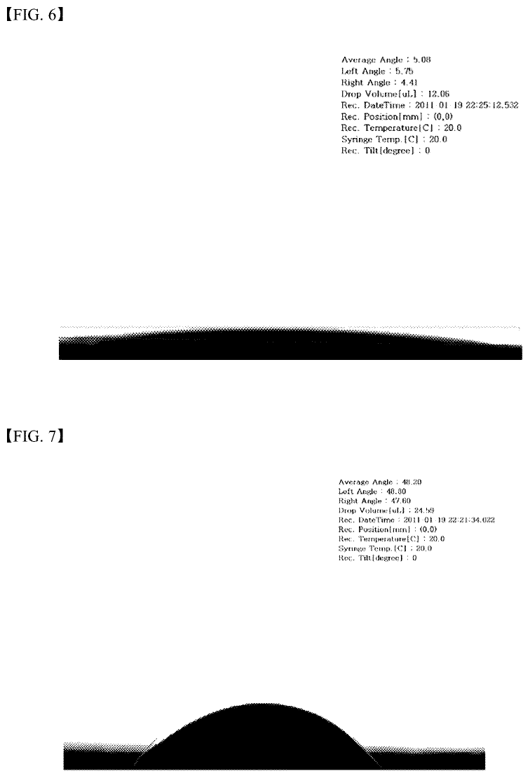

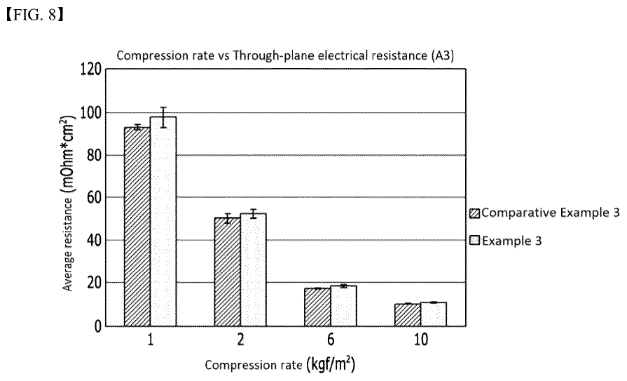

As a result, in the case of Example 1, the contact angle was 0°, confirming that the surface was modified to be superhydrophilic (FIG. 6). It could be seen that in the case of Example 2, even though the PTFE microporous layer was included as an intermediate layer, the contact angle was measured to be 40°, still exhibiting hydrophilicity (FIG. 7).

On the other hand, it could be seen that in the case of Comparative Example 1, the contact angle was 128° (FIG. 4), and in the case of Comparative Example 2, the contact angle was 156° (FIG. 5), both exhibiting hydrophobicity.

From these results, it was found that the gas diffusion layer containing the polymer thin film according to the present invention is hydrophilic and has a well-modified surface, and thus is suitable for use in anion exchange membrane electrolysis.

### Experimental Example 3—Alkali Resistance Test

The alkali resistance of the gas diffusion layer formed with the polymer thin film of Example 1 was tested.

In order to be similar to the environment when using in anion exchange membrane electrolysis, the gas diffusion layer of Example 1 was immersed in a 1M KOH aqueous solution for 3 days, and then contact angle measurement and FT-IR peak change measurement were performed.

The contact angle was measured in the same manner as in Experimental Example 2, and the contact angle was measured to be 0° both before and after alkali resistance test, confirming that it still has superhydrophilic surface properties.

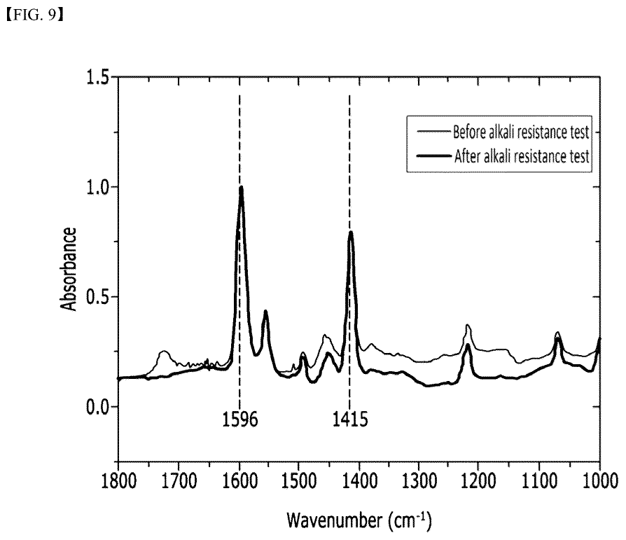

FT-IR was measured before and after alkali resistance test using an FT-IR spectrometer (ALPHA FT-IR Spectrometer, BRUKER), and the resulting peaks were shown in FIG. 8. Pyridine peaks were detected at 1415 cm⁻¹ and 1596 cm⁻¹ at the same level before and after the alkali resistance test, confirming that no change occurred in the composition of the polymer thin film.

In conclusion, it was found that even when the gas diffusion layer of the present invention is used for anion exchange membrane electrolysis under strong alkaline conditions, the polymer thin film does not disappear nor change in the composition, and will sustain the sufficient wettability.

### Experimental Example 4—Observation of Compression Rate Versus Average Electrical Resistance

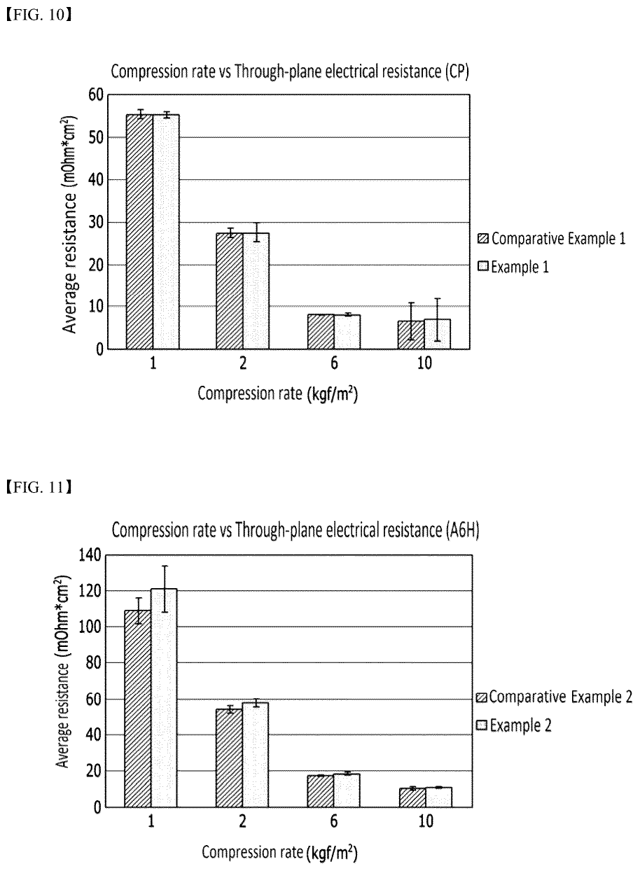

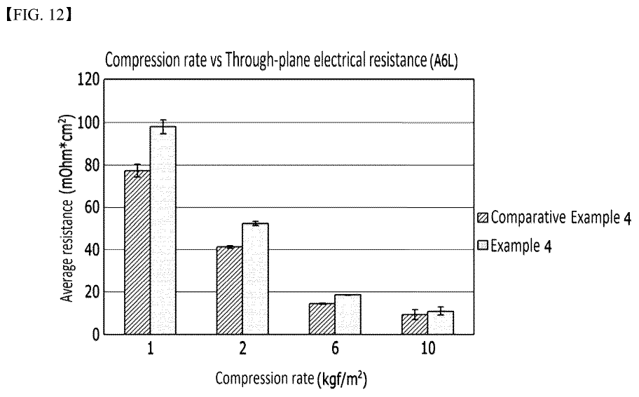

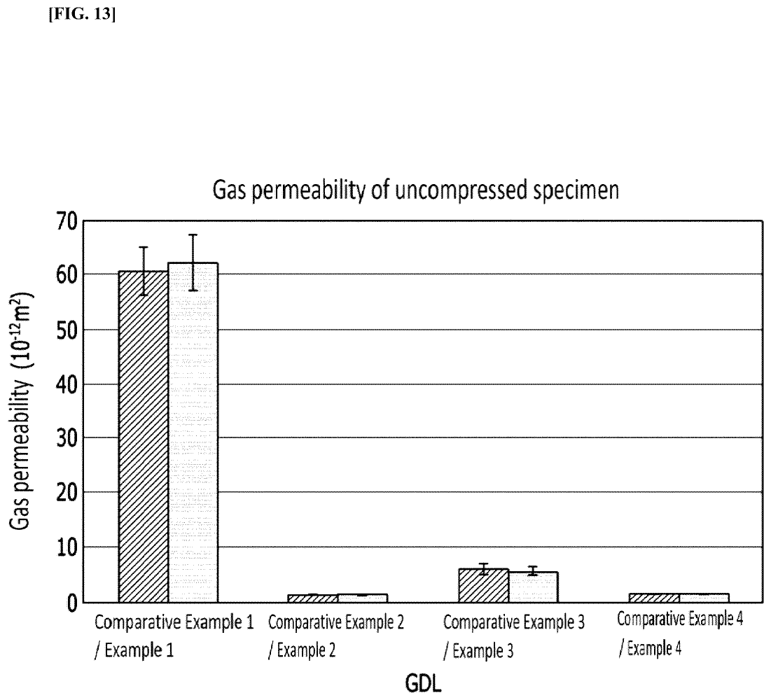

The compression rate versus the electrical resistance of each set of Example 1 and Comparative Example 1, Example 2 and Comparative Example 2, Example 3 and Comparative Example 3, and Example 4 and Comparative Example 4 was observed. A comparison between Example 1 and Comparative Example 1 is shown in FIG. 9, a comparison between Example 2 and Comparative Example 2 is shown in FIG. 10, a comparison between Example 3 and Comparative Example 3 is shown in FIG. 11, and a comparison between Example 4 and Comparative Example 4 is shown in FIG. 12. The overall data is shown in Table 1 below.

The compression rate versus the electrical resistance of the present invention was measured using a device for evaluating GDL basic physical properties (CPRT 10, Korea Institute of Energy Technology's own standard). By randomly contacting the GDL surface with an area of 4.799 cm² and performing measurements three times in total. The measurement was performed in the compression rate range from 0.25 to 10 kgf/cm².

FIGS. 9 to 12 showed that in the case of Examples 1 to 4 in which polymer thin films were deposited, the electrical resistance slightly increased at all compression rates, but this was a very small increase, and was not enough to affect the use of anion exchange membrane electrolysis. In particular, there is little difference when the compression rate increases, which is the environment in which water electrolysis cells are assembled, confirming that the anion exchange membrane is suitable for use in water electrolysis.

TABLE 1
Average resistance (mOhm*cm²)

| Compression rate | | | | |
|---|---|---|---|---|
| (kgf/m²) | 1 | 2 | 6 | 10 |
| Example 1 | 55.4 | 27.5 | 8 | 6.9 |
| Example 2 | 120.8 | 57.4 | 18.1 | 10.6 |
| Example 3 | 97.7 | 52.3 | 18.4 | 11 |
| Example 4 | 77.1 | 41.3 | 14.7 | 9.3 |
| Comparative | 55.4 | 27.5 | 8.2 | 6.6 |
| Example 1 | | | | |
| Comparative | 108.6 | 53.8 | 16.8 | 10.2 |
| Example 2 | | | | |
| Comparative | 93.1 | 50.1 | 17.1 | 10.2 |
| Example 3 | | | | |
| Comparative | 76.9 | 38.2 | 13.1 | 8.8 |
| Example 4 | | | | |

### Experimental Example 5—Observation of Gas Permeability

The gas permeabilities of Example 1 and Comparative Example 1, Example 2 and Comparative Example 2, Example 3 and Comparative Example 3, and Example 4 and Comparative Example 4 were observed, and the results are shown in FIG. 13 and Table 2.

The gas permeability of the present invention was measured using a device for evaluating GDL basic physical properties (CPRT 10, Korea Institute of Energy Technology's own standard). By randomly contacting the GDL surface with an area of 0.332 cm² and performing measurements three times in total, the gas permeability can be determined using the following paper and Equation 1.

The gas permeability was determined using the Trough plane permeability method described in the paper “In-plane and through-plane gas permeability of carbon ber electrode backing layers (Jeff T. Gostick, et al., Sep. 1, 2006),” and the gas permeability (K, unit m²) was calculated according to the following [Equation 1], and shown in FIG. 4.

$$K = \frac{μ}{A / t} \frac{m}{{P}_{1} - {P}_{2}} ( \frac{RT}{{MP}_{agg}} ) \qquad [ Equation 1 ]$$

in Equation 1,
K is the gas permeability,
μ is the dynamic viscosity of the gas used,
A is the area of the cross section through which gas permeated,
t is the thickness of the gas diffusion layer through which the gas penetrated,
m is the flow rate (mass) of gas flowing through a unit area,
P₁ is the pressure before gas permeation,
P₂ is the pressure after gas permeation,
R is the gas constant,
T is the temperature,
M is the weight of the gas used, and
P_{avg} means the average value of P₁ and P₂.

According to FIG. 13, it was confirmed that there was no difference in gas permeability before and after deposition of the polymer thin film.

TABLE 2

| | Gas |
|---|---|
| | permeability |
| | (m²) |
| Example 1 | 62.22 |
| Example 2 | 1.3 |
| Example 3 | 5.41 |
| Example 4 | 1.22 |
| Comparative | 60.56 |
| Example 1 | |
| Comparative | 1.16 |
| Example 2 | |
| Comparative | 5.79 |
| Example 3 | |
| Comparative | 1.25 |
| Example 4 | |

### DESCRIPTION OF REFERENCE NUMERALS

100: gas diffusion layer
10: porous support
20: polymer thin film
30: microporous layer

1. A gas diffusion layer for anion exchange membrane electrolysis comprising:
a porous support; and
a polymer thin film deposited on the whole or a part of the surface of the porous support,
wherein the polymer thin film includes at least one functional group selected from the group consisting of amine, hydroxyl, ester, acid anhydride, carboxyl, epoxy, and pyridine.

2. The gas diffusion layer for anion exchange membrane electrolysis according to claim 1, wherein:
the polymer thin film includes repeating units derived from one or more monomers selected from the group consisting of vinylpyridine, hydroxyalkyl (meth) acrylate, dimethylaminoalkyl (meth) acrylate, dimethylaminoalkyl styrene, ethylene glycol (meth) acrylate, ethylene glycol di(meth) acrylate, styrene-co-maleic anhydride and (meth) acrylic acid.

3. The gas diffusion layer for anion exchange membrane electrolysis according to claim 1, wherein:
the gas diffusion layer for anion exchange membrane electrolysis has a contact angle with water of 50° or less.

4. The gas diffusion layer for anion exchange membrane electrolysis according to claim 1, wherein:
the gas diffusion layer for anion exchange membrane electrolysis has a gas permeability of 1×10⁻¹² m² or more.

5. The gas diffusion layer for anion exchange membrane electrolysis according to claim 1, wherein:
the gas diffusion layer for anion exchange membrane electrolysis has alkali resistance in a 1M KOH aqueous solution.

6. The gas diffusion layer for anion exchange membrane electrolysis according to claim 1, wherein:
the porous support is at least one selected from the group consisting of a porous carbon cloth, a porous carbon felt, a porous carbon paper, a nickel mesh, and a titanium mesh.

7. The gas diffusion layer for anion exchange membrane electrolysis according to claim 1, further comprising a microporous layer containing polytetrafluoroethylene between the porous support and the polymer thin film.

8. A method for manufacturing a gas diffusion layer for anion exchange membrane electrolysis, the method comprising:
preparing a porous support (step 1); and forming a polymer thin film deposited on the whole or a part of the surface of the porous support using an initiated chemical vapor deposition (step 2),
wherein the (step 2) is a step of using a monomer containing at least one functional group selected from the group consisting of amine, hydroxyl, ester, acid anhydride, carboxyl, epoxy, and pyridine as a monomer for the polymer thin film.

9. The method for manufacturing a gas diffusion layer for anion exchange membrane electrolysis according to claim 8, wherein:
the monomer for the polymer thin film in the (step 2) is at least one selected consisting of vinylpyridine, hydroxyalkyl (meth) acrylate, from the group dimethylaminoalkyl (meth) acrylate, dimethylaminoalkyl styrene, ethylene glycol (meth) acrylate, ethylene glycol di(meth) acrylate, styrene-co-maleic anhydride and (meth) acrylic acid-based monomers.

10. The method for manufacturing a gas diffusion layer for anion exchange membrane electrolysis according to claim 8, wherein:
the (step 2) is a step of using at least one selected from the group consisting of tert-butyl peroxide and tert-butyl peroxybenzoate as an initiator for the initiated chemical vapor deposition.

11. The method for manufacturing a gas diffusion layer for anion exchange membrane electrolysis according to claim 8, wherein:
the (step 2) is performed under a pressure in the reactor chamber of 0.01 to 1 Torr.

12. The method for manufacturing a gas diffusion layer for anion exchange membrane electrolysis according to claim 8, wherein:
the (step 2) is performed at a substrate temperature in the reactor of 10 to 50° C.

13. The method for manufacturing a gas diffusion layer for anion exchange membrane electrolysis according to claim 8, wherein:
in the (step 2), a monomer flow rate in the reactor is 1 sccm to 10 sccm.

14. The method for manufacturing a gas diffusion layer for anion exchange membrane electrolysis according to claim 8, wherein:
in the (step 2), an initiator flow rate in the reactor is 1 sccm to 5 sccm.
